(19) United States
(12) Patent Application Publication
(10) Pub. No.: US 2015/0228837 A1
(43) Pub. Date: Aug. 13, 2015

(54) PHOTODETECTOR AND METHOD OF FACRICATING THE SAME

(71) Applicants: National Taiwan University, Taipei (TW); National Applied Research Laboratories, Taipei (TW)

(72) Inventors: Hsuen-Li CHEN, Taipei (TW); Keng-Te LIN, Taipei (TW); Yu-Sheng LAI, Hsinchu (TW); Chen-Chieh YU, Taipei (TW)

(21) Appl. No.: 14/616,890

(22) Filed: Feb. 9, 2015

Related U.S. Application Data
(60) Provisional application No. 61/937,764, filed on Feb. 10, 2014.

(30) Foreign Application Priority Data
Jul. 14, 2014 (TW) 103124103

(51) Int. Cl. H01L 31/108; H01L 31/028

(52) U.S. Cl. CPC H01L 31/108; H01L 31/028; G02B 5/003

(57) ABSTRACT

The present invention provides a photodetector, which comprises a semiconductor substrate and a light absorbing layer (including metal layer, silicide layer) and the opening structures. In addition, a method of fabricating the abovementioned photodetector is also disclosed in the present invention.

### BACKGROUND

1. Field of the Invention

The present invention relates a photodetector, particularly to an infrared photodetector having the opening structure formed in order to increase the Schottky junction area between the light absorbing layer, and method of fabricating the same.

2. Description of the Prior Art

The current infrared photodetector adopts the absorption characteristics of semiconductor material at certain band. When the light is absorbed by the material, the electron-hole pair will be separated, and the electric signal will be outputted as the basis for judging the light intensity. The semiconductor materials often used in the infrared photodetector are germanium (Ge) and indium gallium arsenide (InGaAs) etc. The photodetector made by these materials has good photoelectric conversion efficiency at this infrared band. However, the cost of these materials is higher. They are toxic and hard to be integrated with current semiconductor process technology.

The silicon (Si) wafer is frequently used as the substrate for semiconductor process at present. It is a very inexpensive material, and the development of corresponding process technology is much mature. However, the problem faced by natural silicon substrate is that its energy band gap is only 1.12 eV at room temperature. It is to say when the energy of incident light is lower than 1.12 eV—the wavelength of incident light is larger than 1100 nm—the light cannot be absorbed by the silicon substrate. Thus, the detectable range of wavelength for Si-based photodetector will be limited seriously.

In the conventional technology, the metal nano-antennas structure is formed on the silicon substrate. The metal nano-antennas structure (smaller than 100 nm) is used to absorb light to produce the surface plasmon attenuation, and further jump the Schottky junction generated between metal and silicon substrate, in order to detect infrared. However, the Localized Surface Plasma Resonance (LSPR) produced by this metal nano-antennas structure is not significant at the infrared band. It is limited seriously by the polarization of incident light. The LSPR can only be activated by specific polarization of incident light. Thus, the electric signal output of this metal nano-antennas structure element will be unsatisfactory finally.

It is known that the fabrication method of the abovementioned conventional photodetector requires longer process time, more complex process and higher cost. In addition, it is also a big problem that the conventional technology is limit to the polarization of incident light. Namely, before the loss caused by the carrier formed by the surface plasmon attenuation is not considered, the photodetector fabricated by the abovementioned method is unable to convert the polarized incident light sources into the surface plasmon, it will limit the practicability of actual operation seriously, and cause the loss of some polarized incident light sources surely.

### SUMMARY

In view of this, the present invention provides a photodetector, which comprises a semiconductor substrate, a plurality of opening structures, and a light absorbing layer (including metal layer, silicide layer).

In an embodiment, the abovementioned light absorbing layer of metal layer comprises the gold (Au), silver (Ag), aluminum (Al), copper (Cu), titanium (Ti), nickel (Ni), platinum (Pt), chromium (Cr), tungsten (W), molybdenum (Mo), and cobalt (Co) etc.

In an embodiment, the abovementioned light absorbing layer of silicide layer comprises the platinum-silicon compound (PtₓSi), nickel-silicon compound (NiₓSi), titanium-silicon compound (TiₓSi), cobalt-silicon compound (CoₓSi), tungsten-silicon compound (WₓSi) and molybdenum-silicon compound (MoₓSi) etc., where x is an arbitrary number representing the ratio of metal and silicon.

In an embodiment, the abovementioned opening structure may be periodic structures, or non-periodic structures, which will produce the same effect.

In an embodiment, the depth of the abovementioned opening structures and the thickness of light absorbing layer can be optimized in accordance with the range of detected wavelength. Furthermore, the ratio of the thickness of the absorbing layer to the width of opening structure must be smaller than 0.5.

Another purpose is to provide a fabrication method of the abovementioned photodetector, which comprises the following steps:

Firstly, providing a semiconductor substrate is carried out. Then, forming a plurality of pattern on the semiconductor substrate, and making a plurality of light absorbing layer structures on the pattern of semiconductor substrate. Finally, a light absorbing layer (including metal layer, and silicide layer) is formed over the semiconductor substrate and a plurality of opening structures. The absorbing layer is formed across at least two opening structures.

In an embodiment, the step for forming a plurality of pattern on the abovementioned semiconductor substrate is completed by a lithography process (such as I-line, g-line, E-beam, KrF, ArF, DUV, Extreme UV lithography).

In an embodiment additionally, the step for forming a plurality of opening structures on the pattern of semiconductor substrate is completed by an etching process.

From the following description, it can further understand the features and advantages of the present invention. Please refer to FIG. 1 to FIG. 5D upon reading.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates the fabricating block diagram of the photodetector according to an embodiment;

FIG. 2A illustrates the cross-sectional view for the periodic structure of a photodetector according to an embodiment;

FIG. 2B illustrates the cross-sectional view for the non-periodic structure of a photodetector according to an embodiment;

FIGS. 3A to 3E illustrate the image of scanning electronic microscope for the photodetector according to an embodiment;

FIG. 4A illustrates the cavity effect for the electric field centralization of a photodetector according to an embodiment;

FIG. 4B illustrates the relation between the adjustment of opening structures and the absorbability of metal layer for the photodetector according to an embodiment;

FIG. 4C illustrates the light focusing effect of different incident light wavelength and polarized light for the photodetector according to an embodiment;

FIG. 5A illustrates the responsivity of a photodetector under the radiation of tungsten lamp according to an embodiment of the present invention;

FIG. 5B illustrates the responsivity of a photodetector under the radiation of tunable laser according to an embodiment;

FIG. 5C illustrates the relation between the power of incident light at 1310 nm wavelength and the excess current for the photodetector according to an embodiment; and

FIG. 5D illustrates the relation between the power of incident light at 1550 nm wavelength and the excess current for the photodetector according to an embodiment.

### DESCRIPTION OF THE PREFERRED EMBODIMENT

In the following description, the attached Figures will be used to describe the implementation of the present invention. In the Figures, the same symbol of element is used to represent the same element. In order to explain clearly, the size or thickness of the element may be exaggerated.

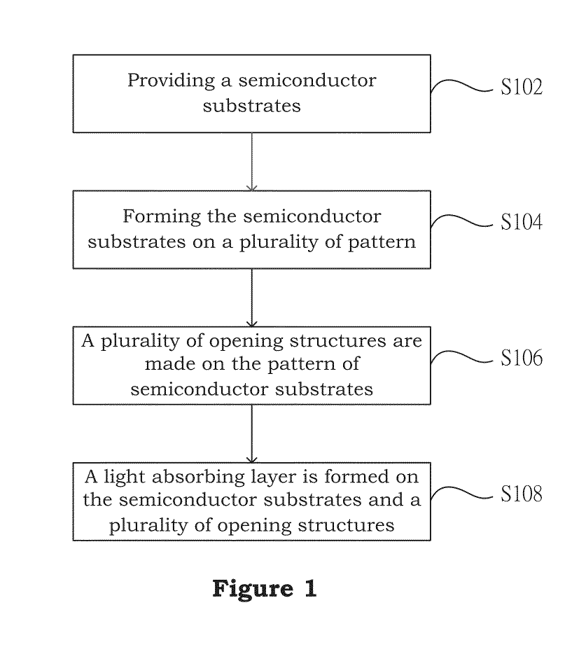

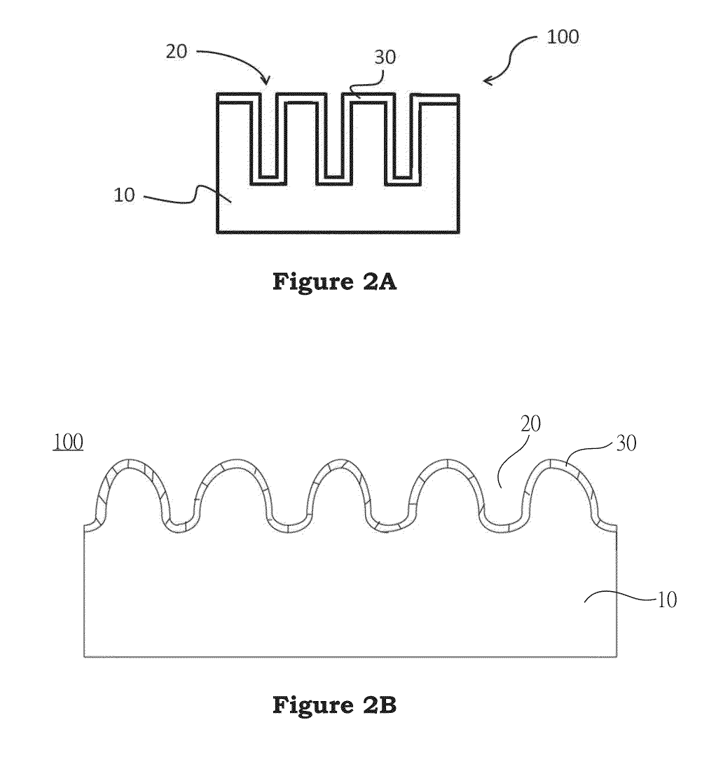

Please refer to FIGS. 1, 2A and 2B and the abovementioned description. FIG. 1 illustrates the fabricating block diagram of the photodetector according to an embodiment. FIG. 2A illustrates the cross-sectional view for the periodic structure of a photodetector according to an embodiment. FIG. 2B illustrates the cross-sectional view for the non-periodic structure of a photodetector according to an embodiment.

Firstly, as shown in Step S102 of FIG. 1, the fabrication method of photodetector provided by the present invention is to provide the semiconductor substrate 10 (also in FIG. 2A, FIG. 2B), such as Si substrate. In an embodiment, the semiconductor substrate 10 may be a negative (n-type) doped Si wafer, and a thermal oxide is grown on the negative (n-type) doped Si wafer. Before the follow-up fabrication processes of photodetector are begun, the pattern should be made on the thermal oxide through etching. Furthermore, the abovementioned thermal oxide can also be used as the light mask of etching for the follow-up lithography process. However, it is noted that the abovementioned embodiment is only used for the demonstrative description, the present invention is not limited by this embodiment.

Then, as shown in Step S104 of FIG. 1, a plurality of pattern is formed on the semiconductor substrate 10, in a preferred embodiment, the Step S104 is completed by the lithography process, such as I-line, g-line, E-beam, KrF, ArF, DUV, Extreme UV lithography, wherein the process cost can be reduced and the yield can be high.

The Step S106 of FIG. 1 is completed by the dry etching process, and then a plurality of opening 20 (also in FIG. 2A, FIG. 2B) structures are made on the pattern of semiconductor substrate 10 in Step S106. The preferred depth of a plurality of opening 20 structures is 1.2 μm, but the present invention is not limited by this. Finally, the metal sputtering process is used to form the light absorbing layer 30 (also in FIG. 2A, FIG. 2B) including metal layer and silicide layer on the Si substrate 10 and the inner wall of the plurality of opening 20. In a preferred embodiment, a light absorbing layer 30 (such as metal layer) is selected from the group consisting of gold (Au), silver (Ag), aluminum (Al), copper (Cu), titanium (Ti), nickel (Ni), platinum (Pt), chromium (Cr), tungsten (W), molybdenum (Mo), cobalt (Co). The light absorbing layer (such as silicide layer) is selected from the group consisting of platinum-silicon compound (PtₓSi), nickel-silicon compound (NiₓSi), titanium-silicon compound (TiₓSi), cobalt-silicon compound (CoₓSi), tungsten-silicon compound (WₓSi) and molybdenum-silicon compound (MoₓSi) (where x is an arbitrary number representing the ratio of metal and silicon). The thickness of the light absorbing layer 30 is 1 nm to 10000 nm, but the present invention is not limited by this. It means in a preferred embodiment, a plurality of opening 20 structures are formed over the semiconductor substrate 10.

However, as the abovementioned description, the purpose of the present invention is to make the Schottky junction with large contact area between metal and silicon substrate.

Finally, in the Step S108, a light absorbing layer 30 is formed over the semiconductor substrate 10 and a plurality of opening 20 structures. The absorbing layer 30 is formed across at least two opening 20 structures. Furthermore, the ratio of the thickness of the absorbing layer 30 to the width of opening 20 structure must be smaller than 0.5.

As the abovementioned description, the photodetector fabricated by the method provided by the present invention is shown in FIG. 2A and FIG. 2B. FIG. 2A illustrates the cross-sectional view for the periodic structure of a photodetector 100 according to an embodiment. The light absorbing layer 30 is formed over the semiconductor substrate 10 and a plurality of opening 20 structures in order to construct the three dimensional (3D) Schottky junctions according to large area on both of the surface, and vertical sides of the opening 20 structure. The cross section of the opening 20 structure looks like the trench array (or the cavity array). Also, the opening 20 structure can be constructed as periodical patterns or non-periodical patterns from top view of the device. In addition, the top-view patterns can be fabricated as square array, rectangle array, circle array, star array, array, and other irregular shapes as the abovementioned.

FIG. 2B illustrates the cross-sectional view for the non-periodic structure of a photodetector 100 according to an embodiment. As shown in the Figure, a plurality of opening 20 structures are formed on the semiconductor substrate 10, and a thin (such as 30 nm only) light absorbing layer 30 is formed over the semiconductor substrate 10, and is formed over the side wall and bottom of a plurality of opening 20 structures. The size and periodic arrangement of the opening 20 structures can be adjusted by I-line lithography process described in Step S104 as follows:

| Label | H065P13 | H07P14 | H075P15 | H08P16 | H085P17 |
|---|---|---|---|---|---|
| Diameter | 0.65 | 0.7 | 0.75 | 0.8 | 0.85 |
| (μm) | | | | | |
| Period (μm) | 1.3 | 1.4 | 1.5 | 1.6 | 1.7 |

For example, the label of H065P13 means the size of the opening 20 structure is 0.65 μm and the period is 1.3 μm (i.e., the distance between two opening structures). Therefore, the size of the opening 20 structure is from 0.65 μm to 0.85 μm, but the present invention is not limited by this. 1.

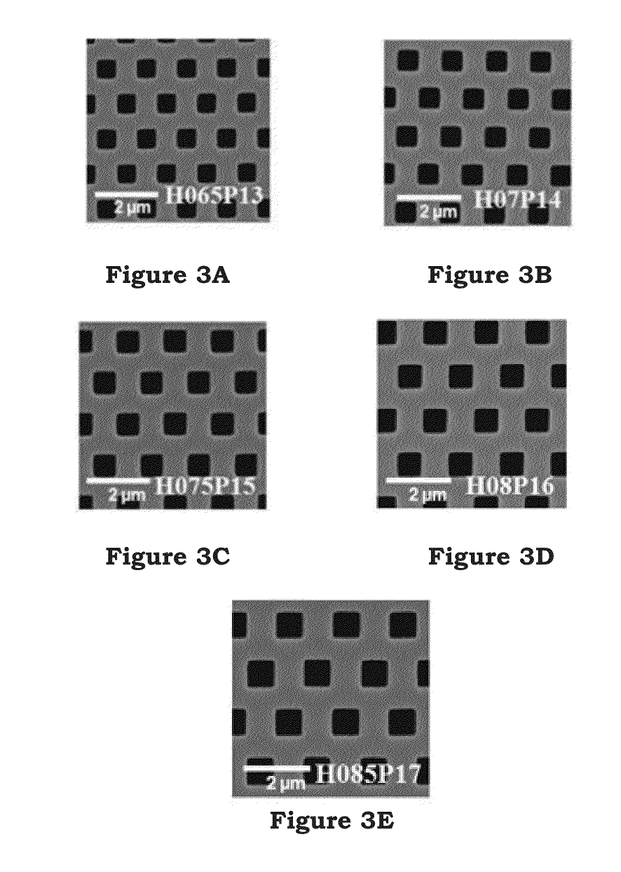

At this moment, the image of scanning electronic microscope for the photodetector is shown in FIG. 3A to FIG. 3E.

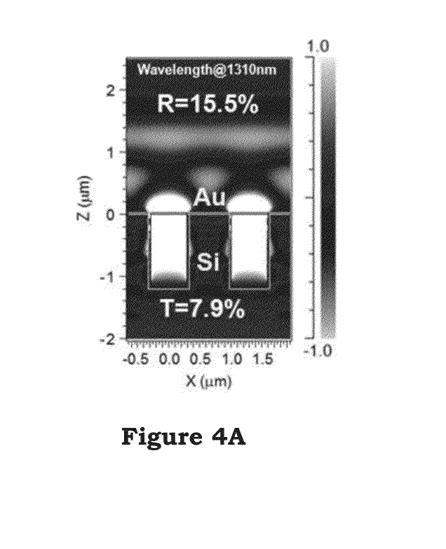

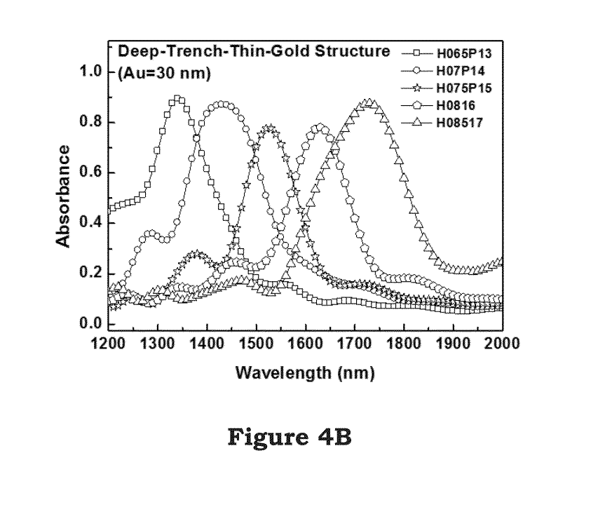

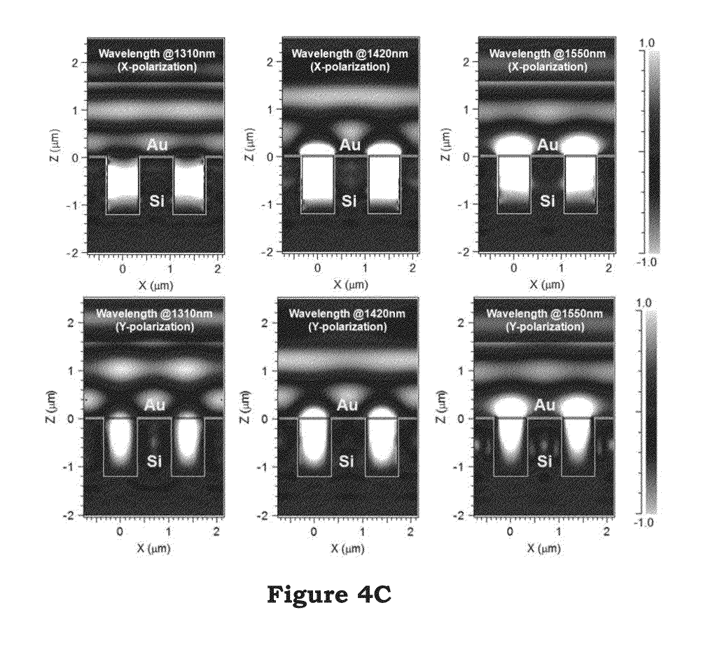

Then, for the optical characteristics of the photodetector provided by the present invention, please refer to FIG. 4A to FIG. 4C. Firstly, a detecting device is placed at 0 nm, 30 nm, 100 nm, 200 nm, 300 nm, 400 nm, 500 nm, and 600 nm under the top surface of the abovementioned opening structure, respectively, in order to observe the focusing effect of electric field of the photodetector provided by the present invention. At this moment, as shown in FIG. 4A, the photodetector provided by the present invention has very strong focusing effect of electric field. After the incident infrared source meets the periodic metal structure, the surface plasmon will be produced to enter into the opening structure. The focusing effect of electric field will be generated, so that most of light will be constrained in the metal structure and absorbed by this thin metal.

Furthermore, as shown in FIG. 4B, the size and periodic arrangement of the opening structure can be adjusted in accordance with the abovementioned table, in order to modulate the light absorbing layer 30 to obtain the wavelength with the strongest absorption. Therefore, the control parameters can be used to further modulate the required measurement wave band.

Finally, please refer to FIG. 4C. FIG. 4C illustrates the light focusing effect of different incident light wavelength and polarized light for the photodetector 100 (also in FIG. 2A, FIG. 2B) according to an embodiment (for H07P14 shown in the abovementioned table). As shown in FIG. 4C, no matter at X-polarization or Y-polarization, the abovementioned opening structure has very strong electric field at 1420 nm of wavelength. In addition, the abovementioned opening structure also have very strong electric field at 1310 nm and 1550 nm due to surface plasmon resonance and cavity effect. It means the abovementioned opening structure in not sensitive to the polarization of incident light. No matter what wavelength or polarized incident light, it can produce excellent focusing effect of electric field.

In order to prove that the photodetector provided by the present invention has very good infrared conversion responsivity, the electric signal will be further measured for this photodetector. It is noted that in order to reach low energy consumption, the polarization is not added in the measurement process.

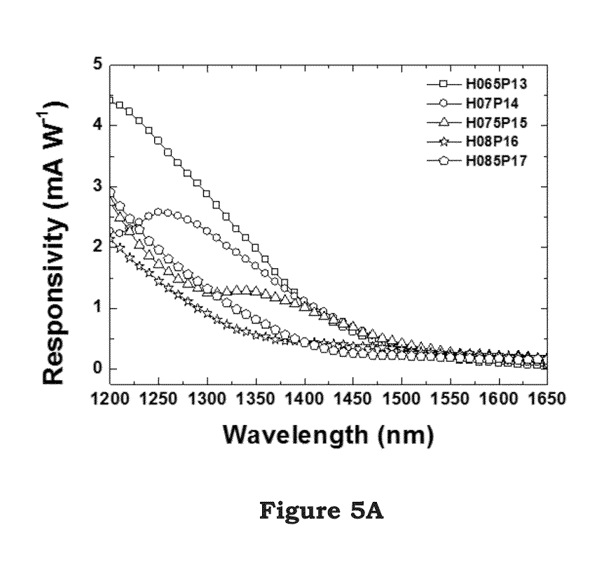

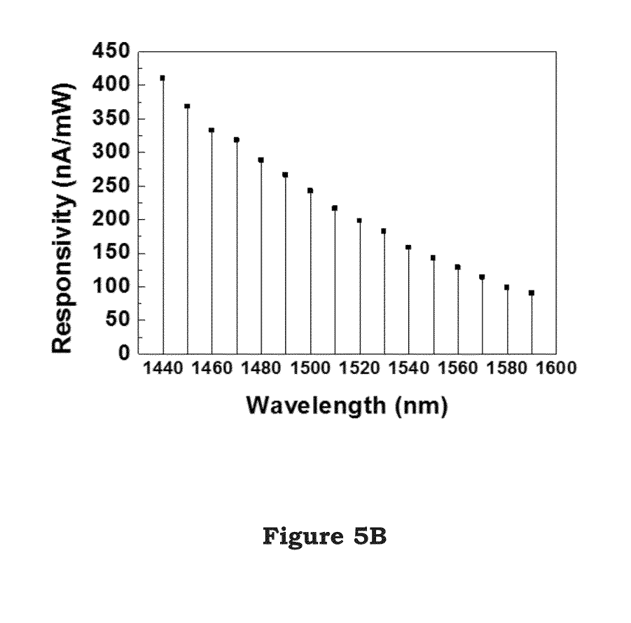

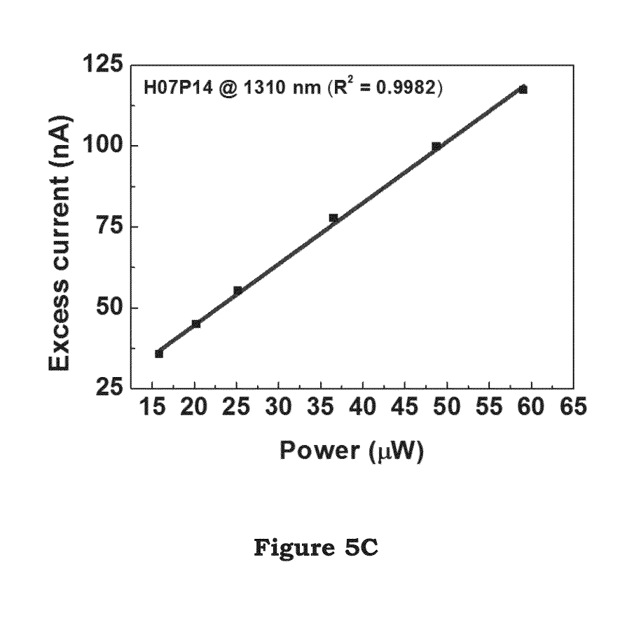

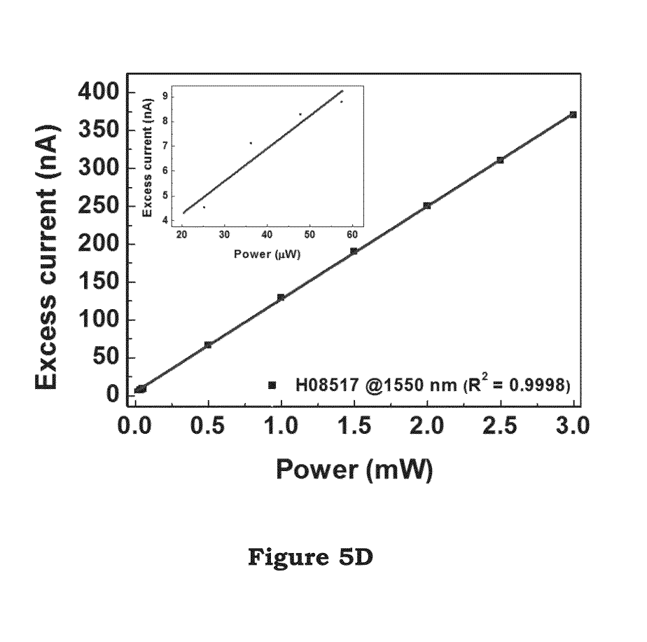

Please refer to FIG. 5A. A polarized light at the wavelength between 1200 nm and 1650 nm is irradiated by a tungsten lamp source. As shown in FIG. 5A, 1.12 eV of photon energy lower than energy band gap of Si can be measured, and good responsivity can be obtained. In addition, the tunable laser can also be used as the device of incident light, and the wavelength is between 1450 nm and 1590 nm.

As shown in FIG. 5B, even irradiated by different device of incident light, the photodetector provided by the present invention also has very good responsivity.

Then, please refer to FIG. 5C. Under fixed incident light wavelength, the incident light with different intensity is irradiated to the photodetector provided by the present invention. As shown in FIG. 5C, when the incident light wavelength of the photodetector is 1310 nm, the electric signal has good linearity (R²=0.9982) at weak intensity of light. As shown in FIG. 5D, when the incident light wavelength of the photodetector is 1550 nm, the electric signal has good linearity (R²=0.9998) at weak or strong intensity of light. Therefore, the photodetector provided by the present invention is actually a Si-based photodetector with wide wave band, high photoelectric conversion efficiency and low energy consumption.

Summarized from the abovementioned description, a plurality of periodic (or non-periodic) opening structure is formed in the present invention. The surface plasmon resonance and cavity effect can be generated by the continuous thin metal structures. The Schottky junction with large contact area can be produced between metal and silicon substrate. The hot electrons can be generated effectively through the attenuation of surface plasmon, in order to increase the photoelectric conversion of this Si-based photodetector. Meantime, through the design of abovementioned pattern, the photodetector will not be limited by the polarization of any incident light, and any polarization of infrared source can be collected effectively. This nontoxic, low-cost photodetector is compatible to current semiconductor process, which not only can reduce the required cost and time of process, but also can break through 1.12 eV energy band gap of silicon substrate. Thus, it is a breakthrough technology for Si-based photodetector photodetector to detect infrared effectively. Similarly, any semiconductor substrate used in the present invention can break through the limitation of energy band gap, and break through the detected wavelength range of semiconductor material.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A photodetector, comprising:
a light absorbing layer is formed over the semiconductor substrate and a plurality of opening structures.

2. The photodetector according to claim 1, wherein said light absorbing layer is selected from the group consisting of gold (Au), silver (Ag), aluminum (Al), copper (Cu), titanium (Ti), nickel (Ni), platinum (Pt), chromium (Cr), tungsten (W), molybdenum (Mo), and cobalt (Co).

3. The photodetector according to claim 1, wherein said light absorbing layer is selected from the group consisting of platinum-silicon compound (PtₓSi), nickel-silicon compound (NiₓSi), titanium-silicon compound (TiₓSi), cobalt-silicon compound (CoₓSi), tungsten-silicon compound (WₓSi) and molybdenum-silicon compound (MoₓSi), where x is an arbitrary number representing a ratio of metal and silicon.

4. The photodetector according to claim 1, wherein said plurality of opening structures are selected from the group consisting of a periodic structure and a non-periodic structure.

5. The photodetector according to claim 1, wherein said absorbing layer formed across at least two opening structures.

6. A photodetector, comprising:
a semiconductor substrate; and
a light absorbing layer is formed over the semiconductor substrate and a plurality of opening structures.

7. The photodetector according to claim 6, wherein said light absorbing layer comprises a metal layer.

8. The photodetector according to claim 7, wherein said metal layer is selected from the group consisting of gold (Au), silver (Ag), aluminum (Al), copper (Cu), titanium (Ti), nickel (Ni), platinum (Pt), chromium (Cr), tungsten (W), molybdenum (Mo), and cobalt (Co).

9. The photodetector according to claim 6, wherein said light absorbing layer comprises a silicide layer.

10. The photodetector according to claim 9, wherein said silicide layer is selected from the group consisting of platinum-silicon compound (PtₓSi), nickel-silicon compound (NiₓSi), titanium-silicon compound (TiₓSi), cobalt-silicon compound (CoₓSi), tungsten-silicon compound (WₓSi) and molybdenum-silicon compound (MoₓSi), where x is an arbitrary number representing a ratio of metal and silicon.

11. The photodetector according to claim 6, wherein said plurality of opening structures are selected from the group consisting of a periodic structure and a non-periodic structure.

12. The photodetector according to claim 6, wherein said absorbing layer formed across at least two opening structures.

13. A photodetector, comprising:
a semiconductor substrate, said semiconductor substrate comprising a plurality of opening structures; and
a light absorbing layer, said light absorbing layer is formed over the semiconductor substrate and a plurality of opening structures.

14. The photodetector according to claim 13, wherein said light absorbing layer comprises a metal layer.

15. The photodetector according to claim 14, wherein said metal layer is selected from the group consisting of gold (Au), silver (Ag), aluminum (Al), copper (Cu), titanium (Ti), nickel (Ni), platinum (Pt), chromium (Cr), tungsten (W), molybdenum (Mo), and cobalt (Co).

16. The photodetector according to claim 13, wherein said light absorbing layer comprises a silicide layer.

17. The photodetector according to claim 16, wherein said silicide layer is selected from the group consisting of platinum-silicon compound (PtₓSi), nickel-silicon compound (NiₓSi), titanium-silicon compound (TiₓSi), cobalt-silicon compound (CoₓSi), tungsten-silicon compound (WₓSi) and molybdenum-silicon compound (MoₓSi), where x is an arbitrary number representing a ratio of metal and silicon.

18. The photodetector according to claim 13, wherein said plurality of opening structures are selected from the group consisting of a periodic structure and a non-periodic structure.

19. The photodetector according to claim 13, wherein said absorbing layer formed across at least two opening structures.
